(19) United States
(12) Patent Application Publication
(10) Pub. No.: US 2025/0212610 A1
(43) Pub. Date: Jun. 26, 2025

(54) DISPLAY DEVICE AND METHOD OF FABRICATING THE SAME

(71) Applicant: Samsung Display Co., LTD., Yongin-si (KR)

(72) Inventors: Jeong Seok LEE, Yongin-si (KR); Woo Yong SUNG, Yongin-si (KR); Hee Jun YANG, Yongin-si (KR)

(21) Appl. No.: 18/742,209

(22) Filed: Jun. 13, 2024

(30) Foreign Application Priority Data
Dec. 26, 2023 (KR) 10-2023-0191121

(51) Int. Cl. H10K 59/122; H10K 59/12; H10K 59/131; H10K 59/80; H10K 71/20; H10K 102/00

(52) U.S. Cl. CPC H10K 59/122; H10K 59/1201; H10K 59/131; H10K 59/80522; H10K 59/873; H10K 71/231; H10K 2102/351

(57) ABSTRACT

A display device includes: a light emitting layer on a light emission area of a substrate; a bank structure including a first bank structure on the pixel defining layer and a second bank structure on the first bank structure; an organic pattern overlapping the light emission area, on the first bank structure, including a same material as that of the light emitting layer, but spaced apart from the light emitting layer; and an electrode pattern on the organic pattern, including a same material as that of the cathode electrode but spaced apart from the cathode electrode, wherein the first bank structure includes a first tip protruded toward the light emission area, and the second bank structure includes a second tip protruded toward the light emission area, and the organic pattern and the electrode pattern overlap the first tip and the second tip in a direction perpendicular to the substrate.

### CROSS-REFERENCE TO RELATED APPLICATION

The present application claims priority to and the benefit of Korean Patent Application No. 10-2023-0191121, filed on Dec. 26, 2023, in the Korean Intellectual Property Office, the entire disclosure of which is incorporated herein by reference.

### BACKGROUND

### 1. Field

Aspects of some embodiments of the present disclosure relate to a display device and a method of fabricating the same.

### 2. Description of the Related Art

With the advancement of the information age, consumer demand for display devices for displaying images has increased in various forms. For example, display devices have been applied to various consumer electronic devices such as smart phones, digital cameras, laptop computers, navigators, and smart televisions. Display devices may include flat panel display device such as a liquid crystal display device, a field emission display device and an organic light emitting display device. Among flat panel display devices, light emitting display devices generally include light emitting elements in which each of pixels of a display panel may self-emit light, thereby displaying images even without a backlight unit that provides the display panel with light.

Recently, with the development of various electronic devices, there is increasing consumer demand for display devices having high resolution. In the case of display devices having high resolution, because high pixel integration may be desirable, an interval between light emitting elements, which overlap each light emission area, may be relatively narrowed. Therefore, display devices having high resolution may be formed by a pattern process of forming individual pixels rather than a process of using a fine metal mask.

As display devices may be incorporated into various electronic devices, display devices having various designs may be desired. For example, when display devices are light emitting display devices, images may be displayed not only on a front portion but also on a side portion bent at each of four edges of the front portion. For example, display devices may include a corner portion located between a first side portion bent at a first side edge of the front portion and a second side portion bent at a second side edge of the front portion.

The above information disclosed in this Background section is only for enhancement of understanding of the background and therefore the information discussed in this Background section does not necessarily constitute prior art.

### SUMMARY

Aspects of some embodiments of the present disclosure include a display device that includes a bank structure and resolves a bending reliability defect occurring as a side portion and a corner portion of the display device is bent.

Other characteristics of embodiments according to the present disclosure include a display device that includes a bank structure and resolves a permeation reliability defect occurring in accordance with permeation of moisture and oxygen.

The characteristics of embodiments according to the present disclosure are not limited to those mentioned above and additional characteristics of embodiments according to the present disclosure, which are not mentioned herein, will be more clearly understood by those skilled in the art from the following description of the present disclosure.

Details of the other embodiments are included in the detailed description and drawings.

According to some embodiments of the present disclosure, a display device includes a substrate including a light emission area and a non-light emission area; a light emitting layer positioned on the light emission area of the substrate; a cathode electrode positioned on the light emitting layer; an auxiliary electrode positioned on the cathode electrode; a pixel defining layer positioned on the non-light emission area of the substrate, defining a first opening; a bank structure including a first bank structure positioned on the pixel defining layer and a second bank structure positioned on the first bank structure, defining a second opening; an organic pattern that overlaps the light emission area, is positioned on the first bank structure, includes the same material as that of the light emitting layer, but is spaced apart from the light emitting layer; and an electrode pattern that is positioned on the organic pattern, includes the same material as that of the cathode electrode but is spaced apart from the cathode electrode, wherein the first bank structure includes a first tip protruded toward the light emission area, and the second bank structure includes a second tip protruded toward the light emission area, and the organic pattern and the electrode pattern overlap the first tip and the second tip in a direction perpendicular to the substrate.

According to some embodiments, the first bank structure may include a first bank layer; and a second bank layer positioned on the first bank layer, including the first tip, and the second bank structure includes a third bank layer; and a fourth bank layer positioned on the third bank layer, including the second tip.

According to some embodiments, the organic pattern may be positioned in contact with the first tip, and the organic pattern and the electrode pattern are in contact with the third bank layer.

According to some embodiments, the auxiliary electrode may be in contact with the first tip and the second tip, and the auxiliary electrode that is in contact with the first tip and the auxiliary electrode that may be in contact with the second tip are integrally formed.

According to some embodiments, the first bank layer and the third bank layer may have electrical conductivity higher than that of the second bank layer and the fourth bank layer.

According to some embodiments, a side of the first bank layer, which may be directed toward the light emission area, includes a first portion with which the light emitting layer is in contact, a second portion with which the cathode electrode is in contact; and a third portion with which the auxiliary electrode is in contact, and the second portion may be positioned between the first portion and the third portion.

According to some embodiments, the side of the first bank layer may be completely covered by the light emitting layer, the cathode electrode and the auxiliary electrode.

According to some embodiments, a side of the third bank layer, which may be directed toward the light emission area, includes a first portion with which the organic pattern is in contact; a second portion with which the electrode pattern is in contact; and a third portion with which the auxiliary electrode may be in contact, and the second portion is positioned between the first portion and the third portion.

According to some embodiments, the side of the third bank layer, which may be directed toward the light emission area, may be completely covered by the organic pattern, the electrode pattern and the auxiliary electrode.

According to some embodiments, the first opening may be completely surrounded by the second opening in a plan view, and the auxiliary electrode is completely surrounded by the fourth bank layer in the plan view.

According to some embodiments, the display device may further include a thin film encapsulation layer positioned on the auxiliary electrode; and an overcoat layer on the thin film encapsulation layer, wherein the thin film encapsulation layer and the overcoat layer overlap the first tip and the second tip in a direction perpendicular to the substrate.

According to some embodiments, the thin film encapsulation layer and the overcoat layer may overlap the first tip and the second tip in a direction parallel with the substrate.

According to some embodiments, the overcoat layer may have a thickness of 8 μm or less at a portion that overlaps the non-light emission area and does not overlap the thin film encapsulation layer.

According to some embodiments of the present disclosure, a display device includes a substrate including a light emission area and a non-light emission area; a first light emitting element on the light emission area of the substrate; a first auxiliary electrode on the first light emitting element; a pixel defining layer on the non-light emission area of the substrate; a bank structure positioned on the pixel defining layer, including a first bank layer, a second bank layer, a third bank layer and a fourth bank layer, which are sequentially stacked; a second light emitting element spaced apart from the first light emitting element with the pixel defining layer interposed therebetween; a second auxiliary electrode on the second light emitting element; a thin film encapsulation layer including a first inorganic layer positioned on the first auxiliary electrode and a second inorganic layer positioned on the second auxiliary electrode; and an overcoat layer on the thin film encapsulation layer, wherein the fourth bank layer includes a first surface in a direction directed toward the thin film encapsulation layer, the first surface is spaced apart from the thin film encapsulation layer in a direction perpendicular to the substrate, the overcoat layer is positioned between the first surface and the thin film encapsulation layer, and the first surface is completely covered by the overcoat layer.

According to some embodiments, the second bank layer may include a first tip more protruded to both sides toward the light emission area than both sides of the first bank layer, the fourth bank layer includes a second tip more protruded to both sides toward the light emission area than both sides of the third bank layer, and the first auxiliary electrode and the second auxiliary electrode are in contact with the first bank layer, the first tip, the third bank layer and the second tip.

According to some embodiments, the first inorganic layer and the second inorganic layer may be spaced apart from each other in a direction parallel with the substrate at a portion overlapped with the non-light emission area.

According to some embodiments, the first auxiliary electrode may include a second surface directed toward the first inorganic layer, the second auxiliary electrode may include a third surface directed toward the second inorganic layer, the second surface and the third surface are spaced apart from each other with the first surface interposed therebetween, and the second surface and the third surface are in contact with the overcoat layer.

According to some embodiments, the first auxiliary electrode and the second auxiliary electrode may be in contact with the second tip, but are not in contact with the first surface.

According to some embodiments, the first light emitting element and the second light emitting element may be in contact with the first bank layer, and are electrically connected to each other by the first bank layer.

According to some embodiments of the present disclosure, a method of fabricating a display device, the method includes forming a substrate including a light emission area and a non-light emission area, forming an anode electrode on the light emission area, forming a sacrificial layer on the anode electrode, and forming a pixel defining material layer, a first bank material layer, a second bank material layer, a third bank material layer and a fourth bank material layer, which completely cover the sacrificial layer and the substrate; forming a photoresist on the fourth bank material layer by exposing a portion overlapped with the anode electrode, and forming a hole exposing the sacrificial layer overlapped with the anode electrode by partially removing the pixel defining material layer, the first bank material layer, the second bank material layer, the third bank material layer and the fourth bank material layer through an etching process, and then removing the sacrificial layer by removing an inner wall of the hole through an etching process and at the same time forming a pixel defining layer, a first bank layer, a second bank layer, a third bank layer and a fourth bank layer by forming a first tip of the second bank material layer, which is more protruded toward the hole than a side of the first bank material layer, and a second tip of the fourth bank material layer, which is more protruded toward the hole than a side of the third bank material layer; and forming a light emitting layer, a cathode electrode, an auxiliary electrode and a thin film encapsulation layer on the anode electrode and the fourth bank layer, forming a hard mask at a portion overlapped with the light emission area and the periphery of the light emission area, forming a light emitting element by removing the light emitting layer, the cathode electrode, the auxiliary electrode and the thin film encapsulation layer, which are positioned at portions where the hard mask is not formed, through an etching process, and exposing an upper surface of the fourth bank layer, wherein the auxiliary electrode is in contact with the first bank layer, the second bank layer, the third bank layer and the fourth bank layer but is not in contact with the upper surface of the fourth bank layer when forming the auxiliary electrode and the thin film encapsulation layer.

According to some embodiments, the display device includes a first bank structure and a second bank structure, which are stacked in a vertical direction of a substrate, and may include an auxiliary electrode, a thin film encapsulation layer and an overcoat layer, which cover the first bank structure and the second bank structure. According to some embodiments, the display device may resolve or reduce instances of a permeation reliability defect by maximizing or increasing a permeation path of moisture and oxygen.

In addition, in the display device according some embodiments, the overcoat layer may be formed with a minimum thickness, so that a bending reliability defect caused by bending of a side portion and a corner portion of the display device may be resolved or reduced.

The characteristics of embodiments of the present disclosure are not limited to those mentioned above and more various characteristics are included in the following description of the present disclosure.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating a display device according to some embodiments;

FIG. 3 is a cross-sectional view illustrating a display layer taken along the line Y-Y′ of FIG. 1;

FIG. 4 is a plan view illustrating arrangement of a light emission area on a front portion of FIG. 2;

FIG. 5 is a schematic cross-sectional view illustrating a display panel taken along the line X1-X1′ of FIG. 4;

FIG. 6 is an enlarged cross-sectional view illustrating an area ‘A’ in FIG. 5;

FIG. 7 is an enlarged cross-sectional view illustrating a bank structure in FIG. 6;

FIG. 8 is a schematic plan view illustrating an area ‘A’ in FIG. 5;

FIG. 9 is an enlarged cross-sectional view illustrating a non-light emission area located between a first light emission area and a second light emission area in FIG. 5; and

FIGS. 10 to 19 are schematic cross-sectional views illustrating a method of fabricating a display device shown in FIG. 5.

### DETAILED DESCRIPTION OF THE DISCLOSURE

Aspects of some embodiments of the present invention will now be described more fully herein with reference to the accompanying drawings, in which aspects of some embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the invention. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, aspects of some embodiments of the present disclosure will be described in more detail with reference to the accompanying drawings.

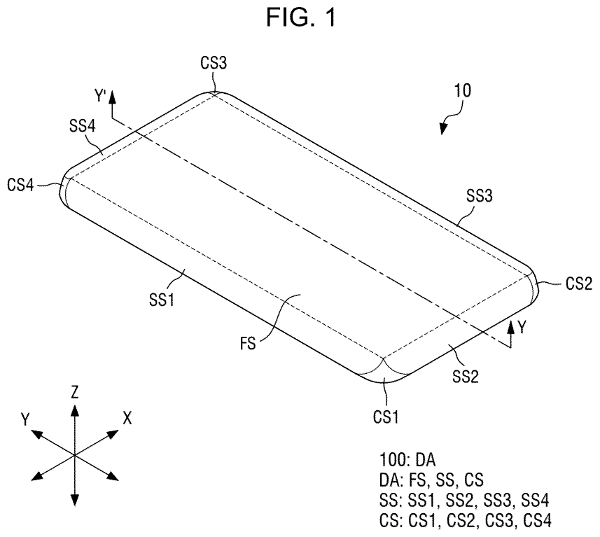

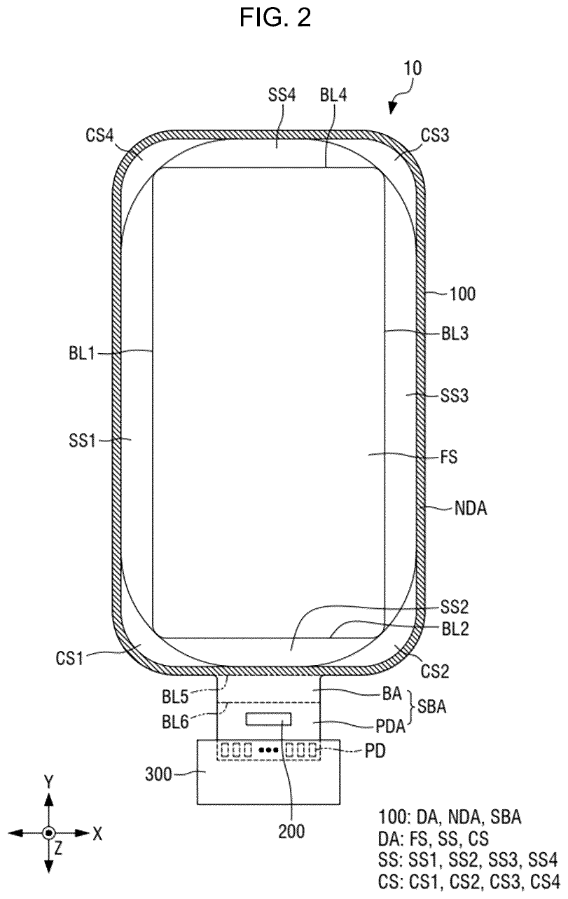

FIG. 1 is a perspective view illustrating an electronic device according to some embodiments. FIG. 2 is a plan view illustrating a display device according to some embodiments.

Referring to FIG. 1, a display device 10 according to some embodiments may be applied to a portable electronic device such as a mobile phone, a smart phone, a tablet personal computer (PC), a mobile communication terminal, an electronic diary, an electronic book, a portable multimedia player (PMP), a navigator and an ultra mobile PC (UMPC). Otherwise, the display device 10 according to some embodiments may be applied to a television, a laptop computer, a monitor, a signboard or a display unit of Internet of things (IoT). Otherwise, the display device 10 according to some embodiments may be applied to a wearable device such as a smart watch, a watch phone, an eyeglasses-type display and a head mounted display (HMD). Otherwise, the display device 10 according to some embodiments may be applied to a dashboard of a vehicle, a center fascia of a vehicle, a center information display (CID) located on a dashboard of a vehicle, a room mirror display that replaces a side mirror of a vehicle or a display located on a rear surface of a front seat as an entertainment for a rear seat of a vehicle.

The display device 10 according to some embodiments may include a display panel 100.

In the present disclosure, a first direction (X-axis direction) is a short-side direction of the display panel 100, and for example, may be a horizontal direction of the display panel 100. A second direction (Y-axis direction) is a long-side direction of the display panel 100, and for example, may be a vertical direction of the display panel 100. A third direction (Z-axis direction) may be a thickness direction of the display panel 100.

The display panel 100 may be a light emitting display panel that includes a light emitting element. For example, the display panel 100 may be an organic light emitting display panel that uses an organic light emitting diode (LED) including an organic light emitting layer, a micro light emitting diode display panel that uses a micro LED, a quantum dot light emitting display panel that uses a quantum dot light emitting diode including a quantum dot light emitting layer, or an inorganic light emitting display panel that uses an inorganic light emitting diode including an inorganic semiconductor. Hereinafter, the description will be based on that the display panel 100 is an organic light emitting display panel.

Referring to FIGS. 1 and 2, the display panel 100 may include a display area DA, a non-display area NDA, and a sub-area SBA. The display area DA refers to an area that includes pixels or light emission areas to display an image. The non-display area NDA and the sub-area SBA will be described later.

The display area DA according to some embodiments may include a front portion FS, a side portion SS, and a corner portion CS.

The front portion FS may have a rectangular planar shape with a short side in the first direction (X-axis direction) and a long side in the second direction (Y-axis direction), but is not limited thereto. The front portion FS may have other polygonal, circular or oval planar shape. In FIG. 1, the front portion FS is illustrated as being formed to be flat, but is not limited thereto. The front portion FS may include a curved surface.

The side portion SS according to some embodiments may include a first side portion SS1, a second side portion SS2, a third side portion SS3, and a fourth side portion SS4.

As shown in FIG. 2, the first side portion SS1 may be extended from a first side of the front portion FS. The first side portion SS1 is bent along a first bending line BL1 of the first side of the front portion FS, and thus may have a first curvature. The first side of the front portion FS may be a left side of the front portion FS as shown in FIG. 1.

The second side portion SS2 may be extended from a second side of the front portion FS. The second side portion SS2 is bent along a second bending line BL2 of the second side of the front portion FS, and thus may have a second curvature. The second curvature may be different from the first curvature, but is not limited thereto. The second side of the front portion FS may be a lower side of the front portion FS.

The third side portion SS3 may be extended from a third side of the front portion FS. The third side portion SS3 is bent along a third bending line BL3 of the third side of the front portion FS, and thus may have a third curvature. The third curvature may be the same as the first curvature, but is not limited thereto. The third side of the front portion FS may be a right side of the front portion FS.

The fourth side portion SS4 may be extended from a fourth side of the front portion FS. The fourth side portion SS4 is bent along a fourth bending line BL4 of the fourth side of the front portion FS, and thus may have a fourth curvature. The fourth curvature may be the same as the first curvature, but is not limited thereto. The fourth side of the front portion FS may be an upper side of the front portion FS.

The corner portion CS according to some embodiments may include a first corner portion CS1, a second corner portion CS2, a third corner portion CS3, and a fourth corner portion CS4.

The first corner portion CS1 may be located between the first side portion SS1 and the second side portion SS2. For example, the first corner portion CS1 may be in contact with a lower side of the first side portion SS1 and a left side of the second side portion SS2. The first corner portion CS1 may be a double curvature area bent by the first curvature of the first side portion SS1 and the second curvature of the second side portion SS2. For this reason, strong tensile strain may be applied to the first corner portion CS1 by a force bent by the first curvature of the first side portion SS1 and a force bent by the second curvature of the second side portion SS2.

The second corner portion CS2 may be located between the second side portion SS2 and the third side portion SS3. For example, the second corner portion CS2 may be in contact with a right side of the second side portion SS2 and a lower side of third side portion SS3. The second corner portion CS2 may be a double curvature area bent by the second curvature of the second side portion SS2 and the third curvature of the third side portion SS3. For this reason, strong tensile strain may be applied to the second corner portion CS2 by a force bent by the second curvature of the second side portion SS2 and a force bent by the third curvature of the third side portion SS3.

The third corner portion CS3 may be located between the third side portion SS3 and the fourth side portion SS4. For example, the third corner portion CS3 may be in contact with an upper side of the third side portion SS3 and a right side of the fourth side portion SS4. The third corner portion CS3 may be a double curvature area bent by the third curvature of the third side portion SS3 and the fourth curvature of the fourth side portion SS4. For this reason, strong tensile strain may be applied to the third corner portion CS3 by a force bent by the third curvature of the third side portion SS3 and a force bent by the fourth curvature of the fourth side portion SS4.

The fourth corner portion CS4 may be located between the first side portion SS1 and the fourth side portion SS4. For example, the fourth corner portion CS4 may be in contact with an upper side of the first side portion SS1 and a left side of the fourth side portion SS4. The fourth corner portion CS4 may be a double curvature area bent by the first curvature of the first side portion SS1 and the fourth curvature of the fourth side portion SS4. For this reason, strong tensile strain may be applied to the fourth corner portion CS4 by a force bent by the first curvature of the first side portion SS1 and a force bent by the fourth curvature of the fourth side portion SS4.

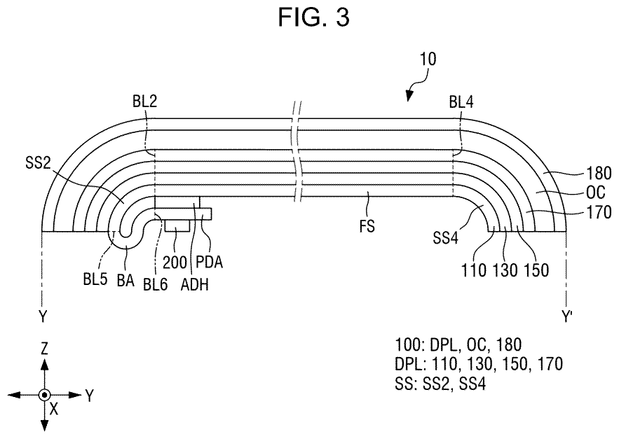

The display device 10 according to some embodiments may include an overcoat layer (OC of FIG. 3) having a minimum thickness, thereby reducing tensile strain caused by the double curvatures of the first corner portion CS1, the second corner portion CS2, the third corner portion CS3 and the fourth corner portion CS4. Details will be described later.

Referring to FIG. 2, the non-display area NDA may be positioned to surround the display area DA. The non-display area NDA may be located outside the side portion SS and the corner portion CS. The non-display area refers to an area that does not include pixels or light emission areas and thus does not display an image.

The sub-area SBA may include a bending area BA and a pad area PDA.

The bending area BA may be extended from the lower side of the second side portion SS2. The bending area BA may be located between the second side portion SS2 and the pad area PDA. A length of the bending area BA in the first direction (X-axis direction) may be shorter than that of the second side portion SS2 in the first direction (X-axis direction). The bending area BA may be bent along a fifth bending line BL5 at the lower side of the second side portion SS2.

The pad area PDA may be extended from a lower side of the bending area BA. A length of the pad area PDA in the first direction (X-axis direction) may be longer than that of the bending area BA in the first direction (X-axis direction), but is not limited thereto. The length of the pad area PDA in the first direction (X-axis direction) may be substantially the same as that of the bending area BA in the first direction (X-axis direction). The pad area PDA may be bent along a sixth bending line BL6 at the lower side of the bending area BA. When the pad area PDA is bent along the sixth bending line BL6, the pad area PDA may be located on a lower surface of the front portion FS.

A display driving circuit 200 and pads PD may be located on the pad area PDA. The display driving circuit 200 may be formed of an integrated circuit IC. The display driving circuit 200 may be attached onto the pad area PDA by a chip on plastic (COP) method or an ultrasonic bonding method. Alternatively, the display driving circuit 200 may be located on a display circuit board 300 located on the pads PD of the pad area PDA.

The display driving board (or display circuit board) 300 may be attached onto the pads PD of the pad area PDA by using an anisotropic conductive film. For this reason, the pads PD of the pad area PDA be electrically connected to the display circuit board 300.

FIG. 3 is a cross-sectional view illustrating a display device 10 taken along line Y-Y′ of FIG. 1.

Referring to FIG. 3, the display panel 100 may include a display layer DPL, an overcoat layer OC and a touch sensor layer 180, and the display layer DPL may include a substrate 110, a thin film transistor layer 130, a display element layer 150, and a thin film encapsulation layer 170.

The substrate 110 according to some embodiments may be located to overlap the front portion FS and the side portion SS, and may be bent by the second bending line BL2 and the fourth bending line BL4. The substrate 110 may be a base substrate or a base member. The substrate 110 may be a flexible substrate capable of being subjected to bending, folding, rolling and the like. For example, the substrate 110 may include a polymer resin such as polyimide (PI), but is not limited thereto. According to some embodiments, the substrate 110 may include a glass material or a metal material.

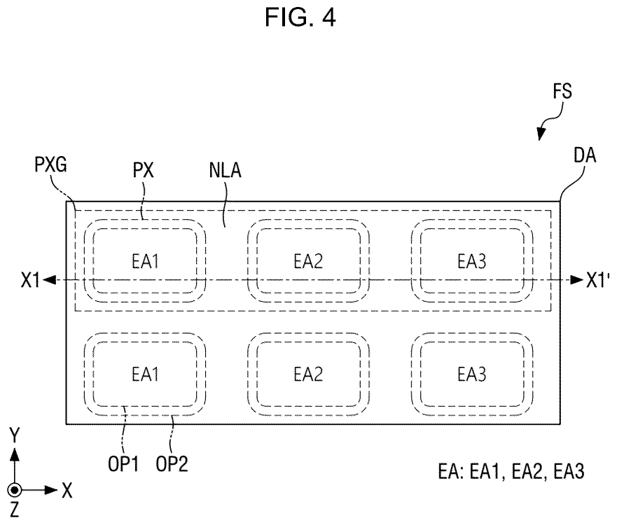

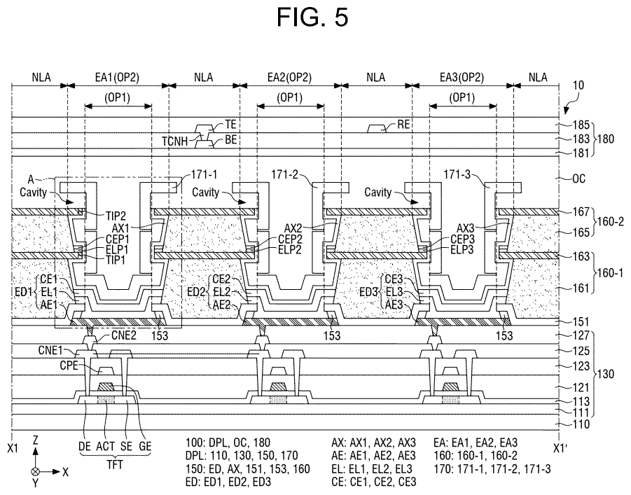

The thin film transistor layer 130 may be located on the substrate 110. The thin film transistor layer 130 according to some embodiments may be arranged to overlap the front portion FS and the side portion SS, and may be bent by the second bending line BL2 and the fourth bending line BL4. The thin film transistor layer 130 may include a plurality of thin film transistors (TFT of FIG. 5) constituting pixels (PX of FIG. 4).

The display element layer 150 may be located on the thin film transistor layer 130. The display element layer 150 according to some embodiments may be arranged to overlap the front portion FS and the side portion SS, and may be bent by the second bending line BL2 and the fourth bending line BL4. The display element layer 150 may include a plurality of light emitting elements (ED of FIG. 5). For example, the display element according to some embodiments may include at least one of an organic light emitting diode including an organic light emitting layer, a quantum dot light emitting diode including a quantum dot light emitting layer, an inorganic light emitting diode including an inorganic semiconductor, or a micro light emitting diode.

The thin film encapsulation layer 170 may be positioned on the display element layer 150. The thin film encapsulation layer 170 according to some embodiments may be arranged to overlap the front portion FS and the side portion SS, and may be bent by the second bending line BL2 and the fourth bending line BL4. The thin film encapsulation layer 170 may protect the display element layer 150 from external oxygen and moisture. The thin film encapsulation layer 170 according to some embodiments may include at least one inorganic layer.

The overcoat layer OC may be positioned on the thin film encapsulation layer 170. The overcoat layer OC according to some embodiments may be arranged to overlap the front portion FS and the side portion SS, and may be bent by the second bending line BL2 and the fourth bending line BL4. The overcoat layer OC may planarize a step difference of a lower structure. In the display device 10 according to some embodiments, a position of a neutral surface caused during bending may be adjusted depending on a thickness of the overcoat layer OC.

The touch sensor layer 180 may be located on the overcoat layer OC. The touch sensor layer 180 according to some embodiments may be arranged to overlap the front portion FS and the side portion SS, and may be bent by the second bending line BL2 and the fourth bending line BL4. The touch sensor layer 180 may sense a touch of a user in a mutual capacitance manner or a self-capacitance manner.

The bending area BA may be bent by the fifth bending line BL5 and located on a lower surface of the second side portion SS2. The pad area PDA may be bent by the sixth bending line BL6 and located on lower surface of the front portion FS. The pad area PDA may be attached to the lower surface of the front portion FS by an adhesive member ADH. The adhesive member ADH may be a pressure sensitive adhesive.

FIG. 4 is a plan view illustrating arrangement of a light emission area EA on the front portion FA of FIG. 2.

Referring to FIG. 4, the display area DA according to some embodiments may include a plurality of first to third light emission areas EA1, EA2 and EA3 and a non-light emission area NLA. The non-light emission area NLA may be positioned to surround the plurality of first to third light emission areas EA1, EA2 and EA3.

The non-light emission area NLA may shield light emitted from each of the plurality of first to third light emission areas EA1, EA2 and EA3. For this reason, the 1 non-light emission area NLA may assist so that light emitted from the plurality of first to third light emission areas EA1, EA2 and EA3 may not be mixed. A pixel defining layer (‘151’ of FIG. 5) and a bank structure (‘160’ of FIG. 5), which will be described later, may be located in the non-light emission area NLA.

The light emission area EA may include a first light emission area EA1, a second light emission area EA2 and a third light emission area EA3, which emit light of different colors. Each of the first to third light emission areas EA1, EA2 and EA3 may emit red, green or blue light, and the color of light emitted from each of the first to third light emission areas EA1, EA2 and EA3 may be different depending on a type of a light emitting element ED that will be described later. For example, the first light emission area EA1 may emit red light of a first color, the second light emission area EA2 may emit green light of a second color and the third light emission area EA3 may emit blue light of a third color, but embodiments according to the present disclosure are not limited thereto. Although the first to third light emission areas EA1, EA2 and EA3 are shown as having the same size and shape, embodiments according to the present disclosure are not limited thereto. The size and shape of each of the first to third light emission areas EA1, EA2 and EA3 may be freely adjusted depending on required characteristics.

The plurality of first to third light emission areas EA1, EA2 and EA3 may be defined by a first opening OP1 and a second opening OP2. For example, the first opening OP1 may be defined by the pixel defining layer (‘151’ of FIG. 5) that will be described later, and the second opening OP2 may be defined by the bank structure (‘160’ of FIG. 5) that will be described later. The second opening OP2 may completely surround the first opening OP1 on a plane (e.g., in a plan view), and the second 1 opening OP2 may be completely surrounded by the non-light emission area NLA on a plane (e.g., in a plan view).

According to some embodiments, at least one first light emission area EA1, at least one second light emission area EA2 and at least one third light emission area EA3, which are arranged to be adjacent to one another, may constitute one pixel group PXG. The pixel group PXG may be a minimum unit for emitting white light. However, various modifications may be made in the type and/or number of the first to third light emission areas EA1, EA2 and EA3 constituting the pixel group PXG depending on the embodiments.

FIG. 5 is a schematic cross-sectional view illustrating a display layer DPL taken along line X1-X1′ of FIG. 4.

Referring to FIG. 5, as described above, the display panel 100 may include a display layer DPL, an overcoat layer OC, and a touch sensor layer 180. The display layer DPL may include a substrate 110, a thin film transistor layer 130, a display element layer 150, and a thin film encapsulation layer 170. Since the substrate 110 has been already mentioned, its redundant description will be omitted.

The thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be located on the substrate 110. The first buffer layer 111 may include an inorganic layer capable of preventing or reducing permeation of contaminants such as air or moisture. For example, the first buffer layer 111 may include a plurality of inorganic layers that are alternately stacked.

The thin film transistor TFT may be located on the first buffer layer 111, and may constitute a pixel circuit connected to each of the pixels. For example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be located on the first buffer layer 111. The active layer ACT may overlap the gate electrode GE in the third direction (Z-axis direction), and may be insulated from the gate electrode GE by the gate insulating layer 113. A portion of the active layer ACT may be conductorized to form the source electrode SE and the drain electrode DE.

The gate electrode GE may be located on the gate insulating layer 113. The gate electrode GE may overlap the active layer ACT with the gate insulating layer 113 interposed therebetween.

The gate insulating layer 113 may be located on the active layer ACT. The gate insulating layer 113 may cover the active layer ACT and the first buffer layer 111, and may insulate the active layer ACT from the gate electrode GE. The gate insulating layer 113 may include a contact hole through which the first connection electrode CNE1 passes.

The first interlayer insulating layer 121 may cover the gate electrode GE and the gate insulating layer 113. The first interlayer insulating layer 121 may include a contact hole through which the first connection electrode CNE1 passes. The contact hole of the first interlayer insulating layer 121 may be connected to a contact hole of the gate insulating layer 113 and a contact hole of the second interlayer insulating layer 123.

The capacitor electrode CPE may be located on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 passes. The contact hole of the second interlayer insulating layer 123 may be connected to the contact hole of the first interlayer insulating layer 121 and the contact hole of the gate insulating layer 113.

The first connection electrode CNE1 may be located on the second interlayer insulating layer 123. The first connection electrode CNE1 may electrically connect the drain electrode DE of the thin film transistor TFT to the second connection electrode CNE2. The first connection electrode CNE1 may be inserted into the contact holes formed in the first interlayer insulating layer 121, the second interlayer insulating layer 123 and the gate insulating layer 113, and thus may be in contact with the drain electrode DE of the thin film transistor TFT.

The first via layer 125 may cover the first connection electrode CNE1 and the second interlayer insulating layer 123. The first via layer 125 may planarize the lower structure. The first via layer 125 may include a contact hole through which the second connection electrode CNE2 passes.

The second connection electrode CNE2 may be located on the first via layer 125. The second connection electrode CNE2 may be inserted into the contact hole formed in the first via layer 125 to contact the first connection electrode CNE1. The second connection electrode CNE2 may electrically connect the first connection electrode CNE1 to an anode electrode AE.

The second via layer 127 may cover the second connection electrode CNE2 and the first via layer 125. The second via layer 127 may include a contact hole through which the anode electrode AE passes.

The display element layer 150 may be located on the second via layer 127. The display element layer 150 may include a light emitting element ED, an auxiliary electrode AX, a pixel defining layer 151, a residual pattern 153, and a bank structure 160.

The light emitting element ED may include an anode electrode AE, a light emitting layer EL, and a cathode electrode CE. The light emitting element ED may include a first light emitting element ED1 located in the first light emission area EA1, a second light emitting element ED2 located in the second light emission area EA2, and a third light emitting element ED3 located in the third light emission area EA3.

The light emitting element ED that overlaps each of the light emission areas EA1, EA2 and EA3 may emit light of different colors depending on the material of the light emitting layer EL. For example, the first light emitting element ED1 may emit red light of a first color, the second light emitting element ED2 may emit green light of a second color, and the third light emitting element ED3 may emit blue light of a third color.

The anode electrode AE may be located on the second via layer 127. The anode electrode AE may be electrically connected to the drain electrode DE of the thin film transistor TFT through the first connection electrode CNE1 and the second connection electrode CNE2.

The anode electrode AE may include a first anode electrode AE1 located in the first light emission area EA1, a second anode electrode AE2 located in the second light emission area EA2, and a third anode electrode AE3 located in the third light emission area EA3. The first anode electrode AE1, the second anode electrode AE2 and the third anode electrode AE3 may be arranged to be spaced apart from one another on the second via layer 127.

According to some embodiments, the anode electrode AE may have a stacked layer structure in which a material layer, which has a high work function, such as indium tin oxide (ITO), indium zinc oxide (IZO), zinc oxide (ZnO) and indium oxide (In₂O₃), and a reflective material layer such as Ag, Mg, Al, Pt, Pb, Pd, Au, Ni, Nd, Ir, Cr, Li, Ca or their mixture are stacked. For example, the anode electrode AE may have a multi-layered structure of ITO/Mg, ITO/MgF, ITO/Ag, and ITO/Ag/ITO, but is not limited thereto.

The pixel defining layer 151 may be positioned on the second via layer 127 and the anode electrode AE. The pixel defining layer 151 may separate and insulate the first to third anode electrodes AE1, AE2 and AE3 from one another. The pixel defining layer 151 according to some embodiments may define the first opening OP1. The pixel defining layer 151 may be entirely located on the second via layer 127 to expose a portion of an upper surface of the anode electrode AE. In other words, the pixel defining layer 151 may expose the anode electrode AE at a portion overlapped with the first opening OP1, and the light emitting layer EL may be directly located on the anode electrode AE at a portion overlapped with the first opening OP1.

The pixel defining layer 151 may include an inorganic insulating material. For example, the pixel defining layer 151 may include silicon oxide, silicon nitride, and silicon oxynitride.

The bank structure 160 may be positioned on the pixel defining layer 151. The bank structure 160 may be located at a portion overlapped with the non-light emission area NLA. The bank structure 160 according to some embodiments may include a first bank structure 160-1 and a second bank structure 160-2. The first bank structure 160-1 and the second bank structure 160-2 may have a structure in which they are sequentially stacked in the third direction (Z-axis direction). The bank structure 160 according to some embodiments may define the second opening OP2, and the first opening OP1 according to some embodiments may be positioned inside the second opening OP2.

The first bank structure 160-1 may be located on the pixel defining layer 151. The first bank structure 160-1 according to some embodiments may assist so that the first to third light emitting elements ED1, ED2 and ED3 spaced apart from one another are formed in the first to third light emission areas EA1, EA2 and EA3, and may electrically connect the first to third light emitting elements ED1, ED2 and ED3. The first bank structure 160-1 according to some embodiments may include a first bank layer 161 and a second bank layer 163, which include their respective metal materials different from each other. The second bank layer 163 according to some embodiments may include a first tip TIP1 protruded toward the light emission area EA.

In the display device 10 according to some embodiments, as the first bank structure 160-1 includes the first tip TIP1, the first to third light emitting layers EL1, EL2 and EL3 and the first to third cathode electrodes CE1, CE2 and CE3, which are arranged to respectively overlap the first to third light emission areas EA1, EA2 and EA3, may be formed without a fine metal mask during the fabricating process of the display device 10. As a result, the display device 10 according to some embodiments may form a plurality of light emitting elements ED applicable to a display device of high resolution, which requires high pixel integration.

The second bank structure 160-2 may be located on the first bank structure 160-1. The second bank structure 160-2 according to some embodiments may include a third bank layer 165 and a fourth bank layer 167, which include their respective materials different from each other. The fourth bank layer 167 according to some embodiments may include a second tip TIP2 protruded toward the light emission area EA.

As the display device 10 according to some embodiments includes the second bank structure 160-2, a permeation path length of moisture and oxygen, which causes oxidation of the cathode electrode CE during the fabricating process of the display device 10, may be maximized. As a result, the display device 10 according to some embodiments may prevent or reduce an oxidation defect of the cathode electrode CE, which is caused during the fabricating process, from occurring.

The light emitting layer EL may be located on the anode electrode AE. The light emitting layer EL may be an organic light emitting layer made of an organic material, and may be formed on the anode electrode AE through a deposition process. When the thin film transistor TFT applies a voltage (e.g., a set or predetermined voltage) to the anode electrode AE and the cathode electrode CE receives a common voltage or a cathode voltage, holes and electrons may move to the light emitting layer EL through a hole transport layer and an electron transport layer, respectively, and may be combined with each other in the light emitting layer EL to emit light.

The light emitting layer EL may include a first light emitting layer EL1, a second light emitting layer EL2 and a third light emitting layer EL3, which are respectively located in the first to third light emission areas EA1, EA2 and EA3. For example, the first light emitting layer EL1 may be a light emitting layer for emitting red light of a first color, the second light emitting layer EL2 may be a light emitting layer for emitting green light of a second color, and the third light emitting layer EL3 may be a light emitting layer for emitting blue light of a third color, but embodiments according to the present disclosure are not limited thereto.

According to some embodiments, the anode electrode AE and the pixel defining layer 151 may be spaced apart from each other in the third direction (Z-axis direction). The residual pattern 153 may be positioned at a portion where the anode electrode AE and the pixel defining layer 151 are spaced apart from each other. The residual pattern 153 will be described later.

The cathode electrode CE may be located on the light emitting layer EL. The cathode electrode CE may include a transparent conductive material so that light generated from the light emitting layer EL may be emitted. The cathode electrode CE may receive a common voltage or a low potential voltage. When the anode electrode AE receives a voltage corresponding to a data voltage and the cathode electrode CE receives a low potential voltage, a potential difference is formed between the anode electrode AE and the cathode electrode CE, so that the light emitting layer EL may emit light.

According to some embodiments, the cathode electrode CE may include a material layer having a small work function, such as Li, Ca, LiF/Ca, LiF/Al, Al, Mg, Ag, Pt, Pd, Ni, Au Nd, Ir, Cr, BaF, Ba or their compound or mixture (e.g., a mixture of Ag and Mg). The cathode electrode CE may further include a transparent metal oxide layer located on the material layer having a small work function.

The cathode electrode CE may include a first cathode electrode CE1, a second cathode electrode CE2 and a third cathode electrode CE3, which are respectively located in the first to third light emission areas EA1, EA2 and EA3. The first cathode electrode CE1 may be located on the first light emitting layer EL1 in the first light emission area EA1, the second cathode electrode CE2 may be located on the second light emitting layer EL2 in the second light emission area EA2, and the third cathode electrode CE3 may be located on the third light emitting layer EL3 in the third light emission area EA3.

The cathode electrode CE according to some embodiments may be spaced apart from another cathode electrode at a portion that overlaps each of the first to third light emission areas EA1, EA2 and EA3. The cathode electrode CE according to some embodiments may not be directly connected to another common electrode, but may be electrically connected to another common electrode through the first bank layer 161.

The auxiliary electrode AX may be located on the cathode electrode CE at a portion overlapped with the light emission area EA. The auxiliary electrode AX may not overlap the non-light emission area NLA. The auxiliary electrode AX may completely cover the cathode electrode CE, and may completely cover a side of the bank structure 160, which is directed toward the light emission area EA. The auxiliary electrode AX may be in contact with the cathode electrode CE and the side of the bank structure 160, which is directed toward the light emission area EA. The auxiliary electrode AX may assist electrical connection between the cathode electrode CE and the bank structure 160, and may assist so that moisture and oxygen are not permeated into the cathode electrode CE.

The auxiliary electrode AX may be made of a transparent conductive oxide (TCO), and for example, a material such as indium tin oxide (ITO) and indium zinc oxide (IZO) may be used as the auxiliary electrode AX.

The auxiliary electrode AX may include a first auxiliary electrode AX1, a second auxiliary electrode AX2, and a third auxiliary electrode AX3, which are respectively located in the first to third light emission areas EA1, EA2 and EA3. The first auxiliary electrode AX1 may be located on the first cathode electrode CE1 in the first light emission area EA1, the second auxiliary electrode AX2 may be located on the second cathode electrode CE2 in the second light emission area EA2, and the third auxiliary electrode AX3 may be located on the third cathode electrode CE3 in the third light emission area EA3.

A plurality of first to third organic patterns ELP1, ELP2 and ELP3 and first to third electrode patterns CEP1, CEP2 and CEP3 may be positioned on the first tip TIP1 of the second bank layer 163. The plurality of first to third organic patterns ELP1, ELP2 and ELP3 and the first to third electrode patterns CEP1, CEP2 and CEP3 may be arranged to surround the periphery of the first opening OP1.

Each of the first to third organic patterns ELP1, ELP2 and ELP3 may include the same material as that of each of the first to third light emitting layers EL1, EL2 and EL3. For example, the first organic pattern ELP1 may include the same material as that of the first light emitting layer EL1, the second organic pattern ELP2 may include the same material as that of the second light emitting layer EL2, and the third organic pattern ELP3 may include the same material as that of the third light emitting layer EL3. The first to third organic patterns ELP1, ELP2 and ELP3 may be marks formed by being disconnected from the first to third light emitting layers EL1, EL2 and EL3 as the second bank layer 163 includes the first tip TIP1.

The first to third electrode patterns CEP1, CEP2 and CEP3 may be located on the first to third organic patterns ELP1, ELP2 and ELP3, respectively. For example, the first electrode pattern CEP1, the second electrode pattern CEP2 and the third electrode pattern CEP3 may be directly located on the first organic pattern ELP1, the second organic pattern ELP2 and the third organic pattern ELP3, respectively. An arrangement relation of the first to third electrode patterns CEP1, CEP2 and CEP3 and the first to third organic patterns ELP1, EL2, and ELP3 may be the same as an arrangement relation of the first to third light emitting layers EL1, EL2 and EL3 and the first to third cathode electrodes CE1, CE2 and CE3. Each of the first to third electrode patterns CEP1, CEP2 and CEP3 may include the same material as that of the first to third cathode electrodes CE1, CE2 and CE3. The first to third electrode patterns CEP1, CEP2 and CEP3 may be marks formed by being disconnected from the first to third cathode electrodes CE1, CE2 and CE3 as the second bank layer 163 includes the first tip TIP1.

The thin film encapsulation layer 170 may be located on the display element layer 150. The thin film encapsulation layer 170 may cover the display element layer 150 along a profile of the lower structure. Therefore, the thin film encapsulation layer 170 may have a step difference. The thin film encapsulation layer 170 may protect the plurality of light emitting elements ED so that instances of contaminants such as moisture and oxygen being permeated into the plurality of light emitting elements ED may be prevented or reduced. The thin film encapsulation layer 170 may cover the side of the bank structure 160, which is directed toward the light emission area EA, as well as the light emitting element ED.

The thin film encapsulation layer 170 may include an inorganic insulating material. The inorganic insulating material may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The thin film encapsulation layer 170 according to some embodiments may include a first inorganic layer 171-1, a second inorganic layer 171-2, and a third inorganic layer 171-3. The first inorganic layer 171-1, the second inorganic layer 171-2 and the third inorganic layer 171-3 may be positioned at portions respectively overlapped with the first light emission area EA1, the second light emission area EA2 and the third light emission area EA3. For example, the first inorganic layer 171-1 may cover the first light emitting element ED1 and the first electrode pattern CEP1, the second inorganic layer 171-2 may cover the second light emitting element ED2 and the second electrode pattern CEP2, and the third inorganic layer 171-3 may cover the third light emitting element ED3 and the third electrode pattern CEP3. The first inorganic layer 171-1, the second inorganic layer 171-2 and the third inorganic layer 171-3 may be spaced apart from one another in the first direction (X-axis direction) at portions overlapped with the non-light emission area NLA.

The thin film encapsulation layer 170 according to some embodiments may be spaced apart from the bank structure 160 in the third direction (Z-axis direction) at a portion overlapped with the non-light emission area NLA, and a cavity may be formed in a space between the thin film encapsulation layer 170 and the bank structure 160.

The overcoat layer OC may be located on the thin film encapsulation layer 170. The overcoat layer OC may planarize the step difference of the lower structure. For example, the overcoat layer OC may planarize the step difference of the thin film encapsulation layer 170 at a portion overlapped with the light emission area EA, and fill the inside of the cavity formed between the bank structure 160 and the thin film encapsulation layer 170 at a portion overlapped with the non-light emission area NLA.

The overcoat layer OC may include a polymer-based material. The polymer-based material may include an acrylic resin, an epoxy resin, a silicone resin polyimide, a silicone acrylic resin, and the like. The overcoat layer OC may be formed by curing a monomer or coating a polymer.

The touch sensor layer 180 may be located on the overcoat layer OC. The touch sensor layer 180 may include a touch buffer layer 181, a connection electrode BE, a touch insulating layer 183, a touch electrode TE, a sensing electrode RE, and a touch passivation layer 185.

The touch buffer layer 181 may be located on the overcoat layer OC. The touch buffer layer 181 may have insulating and optical functions. The touch buffer layer 181 may be an inorganic layer or an organic layer. For example, when the touch buffer layer 181 is an inorganic layer, the touch buffer layer 181 may include at least one of a silicon nitride layer, a silicon oxynitride layer, a silicon oxide layer, a titanium oxide layer or an aluminum oxide layer. When the touch buffer layer 181 is an inorganic layer, the touch buffer layer 181 may include an acrylic resin, an epoxy-based resin, a silicon-based resin polyimide, and a silicon acrylic resin. Optionally, the touch buffer layer 181 may be omitted.

The connection electrode BE may be located on the touch buffer layer 181. The connection electrode BE may be connected to the touch electrode TE through a touch contact hole TCNH. The connection electrode BE may assist so that a plurality of touch electrodes TE are electrically connected.

The connection electrode BE may be formed of a single layer of molybdenum (Mo), titanium (Ti), copper (Cu), aluminum (Al), or indium tin oxide (ITO), or may be formed of a stacked structure (Ti/Al/Ti) of aluminum and titanium, a stacked structure (ITO/Al/ITO) of aluminum and ITO, an APC alloy, or a stacked structure (ITO/APC/ITO) of an APC alloy and ITO.

The insulating layer 183 may cover the touch buffer layer 181 and the connection electrode BE. The touch insulating layer 183 may have insulating and planarization functions. The touch insulating layer 183 may include the same material as that of the touch buffer layer 181.

The touch electrode TE and the sensing electrode RE may be located on the touch insulating layer 183. Each of the touch electrodes TE may not overlap the first to third light emission areas EA1, EA2 and EA3. Each of the touch electrodes TE may be formed of a single layer of molybdenum (Mo), titanium (Ti), copper (Cu), aluminum (Al), or indium tin oxide (ITO), or may be formed of a stacked structure (Ti/Al/Ti) of aluminum and titanium, a stacked structure (ITO/Al/ITO) of aluminum and ITO, an APC alloy or a stacked structure (ITO/APC/ITO) of an APC alloy and ITO.

The touch passivation layer 185 may cover the touch electrode TE, the sensing electrode RE, and the touch insulating layer 183. The touch passivation layer 185 may have insulating and planarization functions. The touch passivation layer 185 may include the same material as that of the touch buffer layer 183.

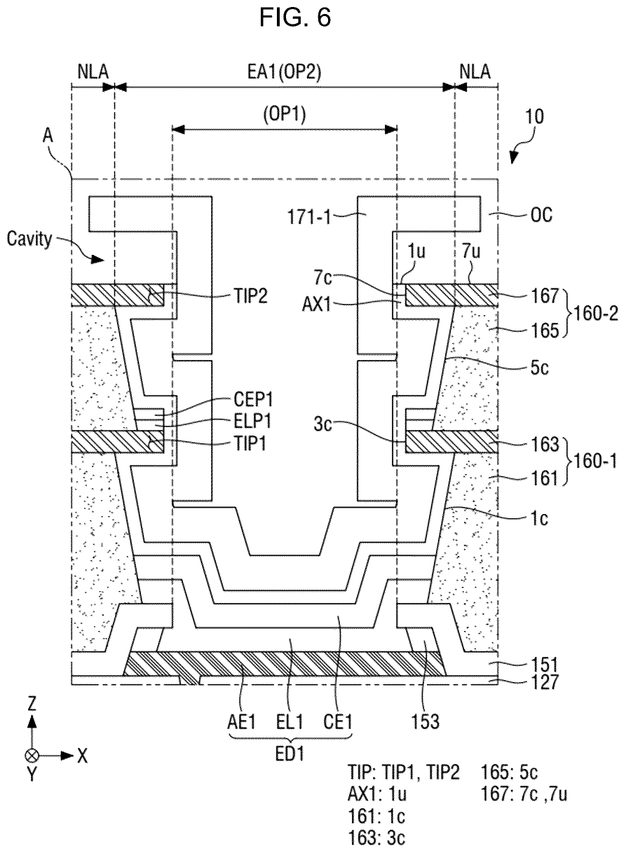

FIG. 6 is an enlarged cross-sectional view illustrating an area ‘A’ in FIG. 5.

Referring to FIG. 6, the pixel defining layer 151 may be positioned on the second via layer 127 and the first anode electrode AE1. The pixel defining layer 151 may be spaced apart from the first anode electrode AE1 in the third direction (Z-axis direction) by overlapping the second opening OP2, and the residual pattern 153 may be positioned between the pixel defining layer 151 and the first anode electrode AE1. The residual pattern 153 may be arranged in contact with both sides of the first light emitting layer EL1 in the first direction (X-axis direction), and may overlap the tip TIP of the bank structure 160 in the third direction (Z-axis direction).

The first bank structure 160-1 may be positioned on the pixel defining layer 151. The first bank structure 160-1 may include a first bank layer 161 and a second bank layer 163, which include different metal materials and structures and perform different functions.

The first bank layer 161 may be positioned in contact with the pixel defining layer 151. The first bank layer 161 may include a metal having high electrical conductivity. For example, the first bank layer 161 may include at least one of aluminum (Al) or copper (Cu).

According to some embodiments, the first bank layer 161 may include a side 1c directed toward the first opening OP1. The side 1c of the first bank layer 161 may be an inclined surface. In other words, the side 1c of the first bank layer 161 may be inclined between the first direction (X-axis direction) and the third direction (Z-axis direction). The side 1c of the first bank layer 161 may include a structure more recessed in the first direction (X-axis direction) than the pixel defining layer 151.

The first light emitting layer EL1 and the first cathode electrode CE1 may be in contact with the side 1c of the first bank layer 161 according to some embodiments. The first light emitting layer EL1 and the first cathode electrode CE1 according to some embodiments may be inclined and deposited in an oblique direction with respect to the first anode electrode AE1 during the fabricating process. Therefore, the first light emitting layer EL1 and the first cathode electrode CE1 may be in contact with the side 1c of the first bank layer 161 at a portion overlapped with the second opening OP2. The fabricating process will be described later.

The second bank layer 163 according to some embodiments may be positioned on the first bank layer 161. The second bank layer 163 may include a metal material having high electrical stability and high adhesion to a metal. The second bank layer 163 may include a metal material that is more stable for etching than the first bank layer 161, and for example, may include any one of molybdenum (Mo), chromium (Cr), gold (Au), titanium (Ti), nickel (Ni) and neodymium (Nd), or their alloy.

According to some embodiments, the second bank layer 163 may include a side 3c directed toward the first opening OP1. The side 3c of the second bank layer 163 may be more protruded toward the first light emission area EA1 than the side 1c of the first bank layer 161. For this reason, the second bank layer 163 may have the first tip TIP1 more protruded toward the first light emission area EA1 than the side 1c of the first bank layer 161. The first tip TIP1 according to some embodiments may be formed due to a difference in etching rates with respect to etching solutions between the first bank layer 161 and the second bank layer 163 during the fabricating process of the display device 10. In other words, the etching rate of the second bank layer 163 may be lower than that of the first bank layer 161 with respect to the same etching solution.

The second bank structure 160-2 according to some embodiments may be positioned on the first bank structure 160-1. The second bank structure 160-2 may include a third bank layer 165 and a fourth bank layer 167, which include different metal materials and structures and perform different functions.

The third bank layer 165 according to some embodiments may be positioned in contact with the second bank layer 163. The third bank layer 165 may include a metal having high electrical conductivity. For example, the third bank layer 165 may include at least one of aluminum (Al) or copper (Cu).

According to some embodiments, the third bank layer 165 may include a side 5c directed toward the first opening OP1. The side 5c of the third bank layer 165 may be an inclined surface. In other words, the side 5c of the third bank layer 165 may be inclined between the first direction (X-axis direction) and the third direction (Z-axis direction). The side 5c of the third bank layer 165 may have a structure that is more recessed toward one side in the first direction (X-axis direction) than the second bank layer 163.

The first organic pattern ELP1 and the first electrode pattern CEP1 may be in contact with the side 5c of the third bank layer 165 according to some embodiments. The first organic pattern ELP1 and the first electrode pattern CEP1 according to some embodiments may be positioned on the first tip TIP1 of the second bank layer 163, and at the same time may be in contact with the side 5c of the third bank layer 165.

The fourth bank layer 167 according to some embodiments may be positioned on the third bank layer 165. The fourth bank layer 167 may include a metal material having high electrical stability and high adhesion to a metal. The fourth bank layer 167 may include a metal material that is more stable for etching than the third bank layer 165, and for example, may include any one of molybdenum (Mo), chromium (Cr), gold (Au), titanium (Ti), nickel (Ni) and neodymium (Nd), or their alloy.

According to some embodiments, the fourth bank layer 167 may include a side 7c directed toward the first opening OP1 and an upper surface 7u directed toward the overcoat layer OC. The side 7c of the fourth bank layer 167 may be more protruded toward the first light emission area EA1 than the side 5c of the third bank layer 165. As a result, the fourth bank layer 167 may have the second tip TIP2 more protruded toward the first light emission area EA1 than the side 5c of the third bank layer 165. The second tip TIP2 according to some embodiments may be formed due to a difference in etching rates with respect to etching solutions between the third bank layer 165 and the fourth bank layer 167 during the fabricating process of the display device 10. In other words, the etching rate of the fourth bank layer 167 may be lower than that of the third bank layer 165 with respect to the same etching solution.

According to some embodiments, the upper surface 7u of the fourth bank layer 167 may be partially covered by the first inorganic layer 171-1, and may be completely in contact with the overcoat layer OC.

The first auxiliary electrode AX1 according to some embodiments may completely cover the first light emitting element ED1 at a portion overlapped with the first opening OP1, and may be in contact with the first cathode electrode CE1. In addition, the first auxiliary electrode AX1 according to some embodiments may cover the side 1c of the first bank layer 161, the first tip TIP1 of the second bank layer 163, the side 5c of the third bank layer 165, and the second tip TIP2 of the fourth bank layer 167 at a portion overlapped with the second opening OP2, and may be in contact with the side 1c of the first bank layer 161, the first tip TIP1 of the second bank layer 163, the side 5c of the third bank layer 165 and the second tip TIP2 of the fourth bank layer 167. In addition, the first auxiliary electrode AX1 may cover the first organic pattern ELP1 and the first electrode pattern CEP1, and may be in contact with the first organic pattern ELP1 and the first electrode pattern CEP1.

According to some embodiments, the first auxiliary electrode AX1 may include an upper surface 1u. The first auxiliary electrode AX1 may be formed to completely cover the upper surface 7u of the fourth bank layer 167 during the fabricating process of the display device 10, and then may be partially etched by a subsequent etching process. Therefore, the fact that the first auxiliary electrode AX1 includes the upper surface 1u may be a result formed as a portion of the first auxiliary electrode AX1 is removed by an etching process. The upper surface 1u of the first auxiliary electrode AX1 may be covered by the overcoat layer OC and the first inorganic layer 171-1, and may be in contact with the overcoat layer OC.

The first inorganic layer 171-1 and the upper surface 7u of the fourth bank layer 167 according to some embodiments may be spaced apart from each other in the third direction (Z-axis direction), and a cavity may be formed between the first inorganic layer 171-1 and the upper surface 7u of the fourth bank layer 167. The first organic pattern ELP1 and the first electrode pattern CEP1 according to some embodiments may be located on the first tip TIP1 and the fourth bank layer 167 of the second bank layer 163 during the fabricating process of the display device 10, and then only a portion located on the second bank layer 163 may remain and the other portion located on the fourth bank layer 167 may be removed by a subsequent etching process.

That is, the cavity may be formed as the first organic pattern ELP1 and the first electrode pattern CEP1 are arranged to be stacked on the fourth bank layer 167 and then removed by a subsequent etching process. The inside of the cavity may be filled with the overcoat layer OC. The fabricating process will be described later.

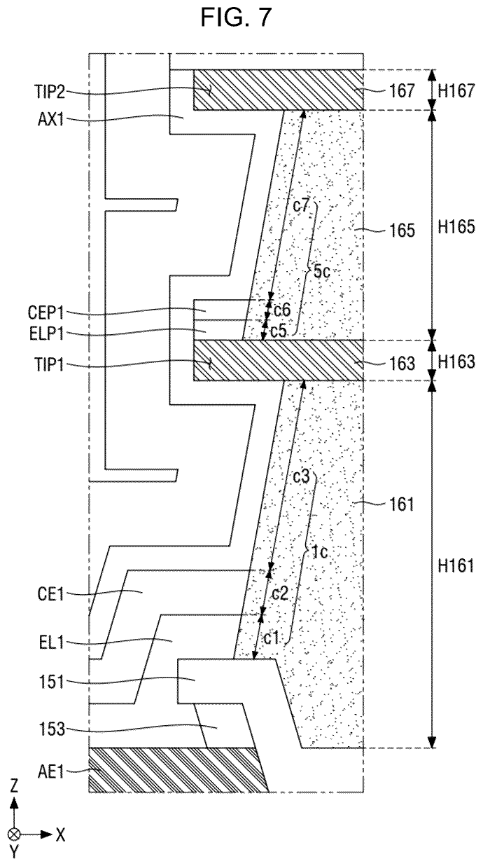

FIG. 7 is an enlarged cross-sectional view illustrating a bank structure 160 in FIG. 6.

Referring to FIG. 7, the side 1c of the first bank layer 161 may include a first portion c1, a second portion c2, and a third portion c3 depending on a contact structure. The first portion c1 may be a portion with which the first light emitting layer EL1 is in contact, the second portion c2 may be a portion with which the first cathode electrode CE1 is in contact, and the third portion c3 may be a portion with which the first auxiliary electrode AX1 is in contact. That is, the side 1c of the first bank layer 161 may be completely covered by the first light emitting layer EL1, the first cathode electrode CE1 and the first auxiliary electrode AX1.

According to some embodiments, the side 5c of the third bank layer 165 may include a first portion c5, a second portion c6, and a third portion c7 depending on a contact structure. The first portion c5 may be a portion with which the first organic pattern ELP1 is in contact, the second portion c6 may be a portion with which the first electrode pattern CEP1 is in contact, and the third portion c7 may be a portion with which the first auxiliary electrode AX1 is in contact. The first auxiliary electrode AX1 that is in contact with the third portion c3 and the first auxiliary electrode AX1 that is in contact with the third portion c7 may be integrally formed. The side 5c of the third bank layer 165 may be completely covered by the first organic pattern ELP1, the first electrode pattern CEP1 and the first auxiliary electrode AX1.

According to some embodiments, a height H161 of the first bank layer 161 according to some embodiments may be higher than a height H163 of the second bank layer 163. For example, the height H161 of the first bank layer 161 may range from 0.3 μm to 1 μm and the height H163 of the second bank layer 163 may range from 0.1 μm to 0.2 μm, but embodiments according to the present disclosure are not limited thereto. In addition, a height H165 of the third bank layer 165 according to some embodiments may be higher than a height H167 of the fourth bank layer 167. For example, the height H165 of the third bank layer 165 may range from 0.3 μm to 1 μm and the height H167 of the fourth bank layer 167 may range from 0.1 μm to 0.2 μm, but embodiments according to the present disclosure are not limited thereto. Also, according to some embodiments, the height H165 of the third bank layer 165 may be smaller than or equal to the height H161 of the first bank layer 161.

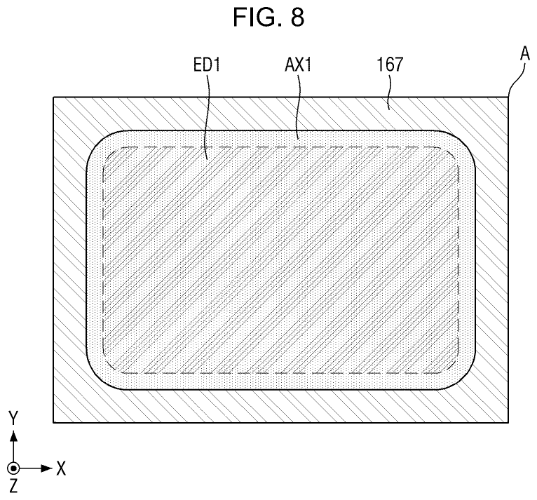

FIG. 8 is a schematic plan view illustrating an area ‘A’ in FIG. 5.

Referring to FIG. 8, the first light emitting element ED1 according to some embodiments may be completely covered by the first auxiliary electrode AX1 on a plane (e.g., in a plan view). That is, an area of the first auxiliary electrode AX1 may be larger than that of the first light emitting element ED1 on a plane (e.g., in a plan view), and the first light emitting element ED1 may be positioned inside the first auxiliary electrode AX1.

In addition, the first auxiliary electrode AX1 may be completely surrounded by the fourth bank layer 167 on a plane (e.g., in a plan view). In other words, the fourth bank layer 167 may completely surround the first auxiliary electrode AX1 and the light emitting element ED1 while exposing the first auxiliary electrode AX1 and the light emitting element ED1 on a plane (e.g., in a plan view).

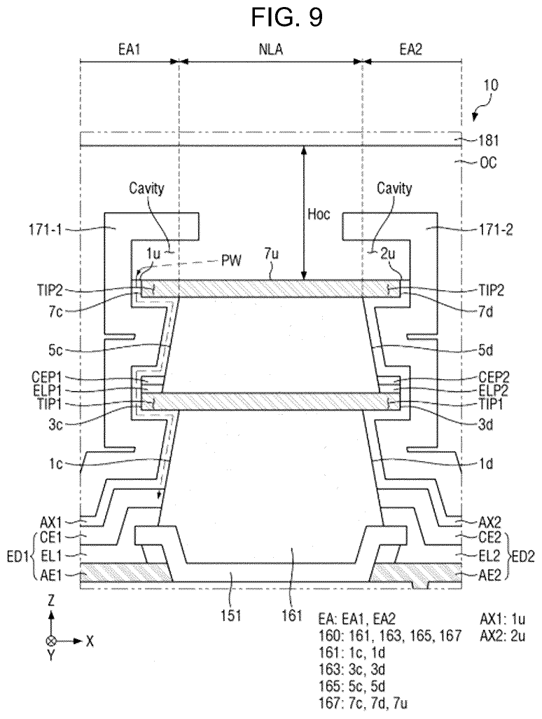

FIG. 9 is an enlarged cross-sectional view illustrating a non-light emission area NLA located between a first light emission area EA1 and a second light emission area EA2 in FIG. 5.

Referring to FIG. 9, the first light emission area EA1 and the second light emission area EA2 may be spaced apart from each other with the non-light emission area NLA interposed therebetween.

The first anode electrode AE1 and the second anode electrode AE2 according to some embodiments may be spaced apart from each other in the first direction (X-axis direction) with the pixel defining layer 151 interposed therebetween.

According to some embodiments, the first bank layer 161 may include a side 1c directed toward the first light emission area EA1 and a side 1d directed toward the second light emission area EA2. The first light emitting layer EL1 and the first cathode electrode CE1 may be in contact with the side 1c directed toward the first light emission area EA1, and the second light emitting layer EL2 and the second cathode electrode CE2 may be in contact with the side 1d directed toward the second light emission area EA2. The first light emitting layer EL1 and the second light emitting layer EL2 according to some embodiments may be spaced apart from each other in the first direction (X-axis direction) with the first bank layer 161 interposed therebetween, and the first cathode electrode CE1 and the second cathode electrode CE2 according to some embodiments may be spaced apart from each other in the first direction (X-axis direction) with the first bank layer 161 interposed therebetween. The first cathode electrode CE1 and the second cathode electrode CE2 may be electrically connected to each other by the first bank layer 161. In other words, the first light emitting element ED1 and the second light emitting element ED2 according to some embodiments may be spaced apart from each other with the pixel defining layer 151 and the bank structure 160, which are interposed therebetween.

According to some embodiments, the second bank layer 163 may include a side 3c directed toward the first light emission area EA1 and a side 3d directed toward the second light emission area EA2. The side 3c directed toward the first light emission area EA1 may be more protruded to the other side in the first direction (X-axis direction) toward the first light emission area EA1 than the side 1c of the first bank layer 161, and the side 3d directed toward the second light emission area EA2 may be more protruded to one side in the first direction (X-axis direction) toward the second light emission area EA2 than the side 1d of the first bank layer 161. Therefore, the second bank layer 163 may have the first tip TIP1 protruded to both sides toward the light emission area EA.

According to some embodiments, the first organic pattern ELP1 and the first electrode pattern CEP1 may be positioned on the first tip TIP1 at a portion overlapped with the first light emission area EA1, and the second organic pattern ELP2 and the second electrode pattern CEP2 may be positioned on the first tip TIP1 at a portion overlapped with the second light emission area EA2.

According to some embodiments, the third bank layer 165 may include a side 5c directed toward the first light emission area EA1 and a side 5d directed toward the second light emission area EA2. The first organic pattern ELP1 and the first electrode pattern CEP1 may be in contact with the side 5c directed toward the first light emission area EA1, and the second organic pattern ELP2 and the second electrode pattern CEP2 may be in contact with the side 5d directed toward the second light emission area EA2. The first organic pattern ELP1 and the second organic pattern ELP2 according to some embodiments may be spaced apart from each other in the first direction (X-axis direction) with the third bank layer 165 interposed therebetween, and the first electrode pattern CEP1 and the second electrode pattern CEP2 according to some embodiments may be spaced apart from each other in the first direction (X-axis direction) with the third bank layer 165 interposed therebetween.

According to some embodiments, the fourth bank layer 167 may include a side 7c directed toward the first light emission area EA1 and a side 7d directed toward the second light emission area EA2. The side 7c directed toward the first light emission area EA1 may be more protruded to the other side in the first direction (X-axis direction) toward the first light emission area EA1 than the side 5c of the third bank layer 165, and the side 7d directed toward the second light emission area EA2 may be more protruded to one side in the first direction (X-axis direction) toward the second light emission area EA2 than the side 5d of the third bank layer 165. Therefore, the fourth bank layer 167 may have a second tip TIP2 protruded to both sides toward the light emission area EA.

The first auxiliary electrode AX1 and the second auxiliary electrode AX2 may be spaced apart from each other with the pixel defining layer 151 and the bank structure 160, which are interposed therebetween. The first auxiliary electrode AX1 and the second auxiliary electrode AX2 may cover the first tip TIP1 of the second bank layer 163 and the second tip TIP2 of the fourth bank layer 167 at a uniform thickness along a profile formed by the first tip TIP1 and the second tip TIP2. Therefore, the first auxiliary electrode AX1 and the second auxiliary electrode AX2 may form a permeation path PW of moisture and oxygen introduced into the display device 10 as long as possible, thereby assisting the first cathode electrode CE1 and the second cathode electrode CE2 so that oxidation by moisture and oxygen may be prevented or reduced. For convenience of description, although the permeation path PW of moisture and oxygen introduced through the first auxiliary electrode AX1 is shown in the drawing, the permeation path of moisture and oxygen introduced through the second auxiliary electrode AX2 may also have similar characteristics.

According to some embodiments, the first auxiliary electrode AX1 may include an upper surface 1u directed toward the first inorganic layer 171-1, and the second auxiliary electrode AX2 may include an upper surface 2u directed toward the second inorganic layer 171-2. The upper surface 1u of the first auxiliary electrode AX1 and the upper surface 2u of the second auxiliary electrode AX2 may be spaced apart from each other in the first direction (X-axis direction) with the upper surface 7u of the fourth bank layer 167, which is interposed therebetween. The upper surface 1u of the first auxiliary electrode AX1 may be spaced apart from the first inorganic layer 171-1 in the third direction (Z-axis direction), and the upper surface 2u of the second auxiliary electrode AX2 may be spaced apart from the second inorganic layer 171-2 in the third direction (Z-axis direction). In addition, the upper surface 1u of the first auxiliary electrode AX1 may be covered by the first inorganic layer 171-1 and the overcoat layer OC, and may be in contact with the overcoat layer OC. Also, the upper surface 2u of the second auxiliary electrode AX2 may be covered by the second inorganic layer 171-2 and the overcoat layer OC, and may be in contact with the overcoat layer OC.

The first inorganic layer 171-1 according to some embodiments may overlap the first tip TIP1 and the second tip TIP2 in the third direction (Z-axis direction) at a portion overlapped with the light emission area EA, and the second inorganic layer 171-2 according to some embodiments may overlap the first tip TIP1 and the second tip TIP2 in the third direction (Z-axis direction) at a portion overlapped with the light emission area EA. In addition, the first inorganic layer 171-1 and the second inorganic layer 171-2 according to some embodiments may be spaced apart from each other in the first direction (X-axis direction) at a portion overlapped with the non-light emission area NLA. In other words, the first inorganic layer 171-1 and the second inorganic layer 171-2 according to some embodiments may be spaced apart from each other in the first direction (X-axis direction) at a portion overlapped with the non-light emission area NLA with the overcoat layer OC interposed therebetween.

The overcoat layer OC may planarize a step difference formed by the first inorganic layer 171-1 and the second inorganic layer 171-2 at a portion overlapped with the light emission area EA. Also, the overcoat layer OC may fill the inside of a cavity formed by overlapping the first inorganic layer 171-1 and the second inorganic layer 171-2 at portions overlapped with the light emission area EA and the non-light emission area NLA.

As described above with reference to FIGS. 1 to 9, the display device 10 according to some embodiments may have a side portion SS and a corner portion CS. Since the side portion SS and the corner portion CS have bending properties, tensile strain may be generated. In particular, strong tensile strain may be generated in the corner portion CS having a double curvature, and the strong tensile strain may sometimes cause a reliability defect.

The display device 10 according to some embodiments may minimize or reduce tensile strain formed on the corner portion CS and the side portion SS by adjusting a height Hoc of the overcoat layer OC. In other words, the display device 10 according to some embodiments may adjust a position of a neutral surface with respect to tensile strain by adjusting the height Hoc of the overcoat layer OC, whereby a reliability defect against bending may be resolved.

According to some embodiments, the height Hoc of the overcoat layer OC from the upper surface 7u of the fourth bank layer 167 to the touch buffer layer 181 may be 8 μm or less.

In other words, as the display device 10 according to some embodiments includes a bank structure 160 including a first bank structure 160-1 and a second bank structure 160-2, which are stacked in the third direction (Z-axis direction), and an auxiliary electrode AX, the permeation path PW of moisture and oxygen may be formed as long as possible, whereby a reliability defect in which the cathode electrode CE is oxidized may be resolved.

In addition, the display device 10 according to some embodiments may include the first to third inorganic layers 171-1,171-2 and 171-3 covering the first to third light emitting elements ED1, ED2 and ED3, respectively, to completely seal the first to third cathode electrodes CE1, CE2 and CE3, thereby resolving a reliability defect in which the cathode electrode CE is oxidized.

In addition, the display device 10 may include an overcoat layer OC having a height of 8 μm or less, thereby resolving a reliability defect caused by tensile strain caused during bending of the display device 10.

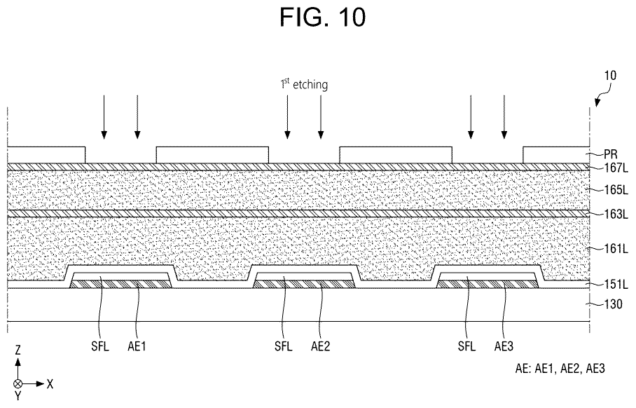

FIGS. 10 to 19 are schematic cross-sectional views illustrating a method of fabricating a display device 10 shown in FIG. 5. Hereinafter, the fabricating process of the display layer DPL, the thin film encapsulation layer 170 and the overcoat layer OC, which are shown in FIG. 5, will be described with respect to the formation order of each layer.

Referring to FIG. 10, a plurality of anode electrodes AE, a sacrificial layer SFL, a pixel defining material layer 151L, and first to fourth bank material layers 161L, 163L, 165L and 167L are formed on the thin film transistor layer 130. According to some embodiments, the thin film transistor layer 130 may be located on the substrate 110, and the structure of the thin film transistor layer 130 is the same as that described above with reference to FIG. 5. A detailed description will be omitted.

The anode electrode AE may include first to third anode electrodes AE1, AE2 and AE3 arranged to be spaced apart from one another on the thin film transistor layer 130. The sacrificial layer SFL may be located on each of the first to third anode electrodes AE1, AE2 and AE3. The sacrificial layer SFL may assist so that upper surfaces of the first to third anode electrodes AE1, AE2 and AE3 are not in contact with the pixel defining material layer 151L.

The sacrificial layer SFL may include an oxide semiconductor. For example, the sacrificial layer SFL may include at least one of indium gallium zinc oxide (IGZO), zinc tin oxide (ZTO), or indium tin oxide (IZO).

The pixel defining material layer 151L and the first to fourth bank material layers 161L, 163L, 165L and 167L may be located on the first to third anode electrodes AE1, AE2 and AE3 and the sacrificial layer SFL. The pixel defining material layer 151L may be arranged to entirely cover the sacrificial layer SFL and the thin film transistor layer 130, and the bank material layers 161L, 163L, 165L and 167L may be arranged to entirely cover the pixel defining material layer 151L. The first bank material layer 161L may be directly located on the pixel defining material layer 151L, and the second bank material layer 163L, the third bank material layer 165L and the fourth bank material layer 167L may be sequentially arranged on the first bank material layer 161L.

Next, a photoresist PR is formed on the fourth bank material layer 167L while exposing a portion overlapped with the anode electrode AE. Subsequently, a first etching process of etching a portion of the pixel defining material layer 151L and the first to fourth bank material layers 161L, 163L, 165L and 167L using the photoresist PR as a mask is performed.

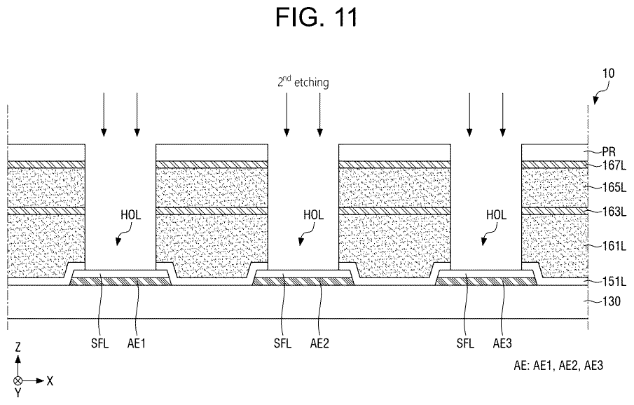

For example, the first etching process may be performed by dry etching. As the first etching process is performed by a dry etching process, portions of the pixel defining material layer 151L and the first to fourth bank material layers 161L, 163L, 165L and 167L, which overlap the anode electrode AE, may be isotropically etched. Through the present process, as shown in FIG. 11, a hole HOL may be

formed in a portion overlapped with the first to third anode electrodes AE1, AE2 and AE3, and the sacrificial layer SFL located on the anode electrode AE may be exposed.

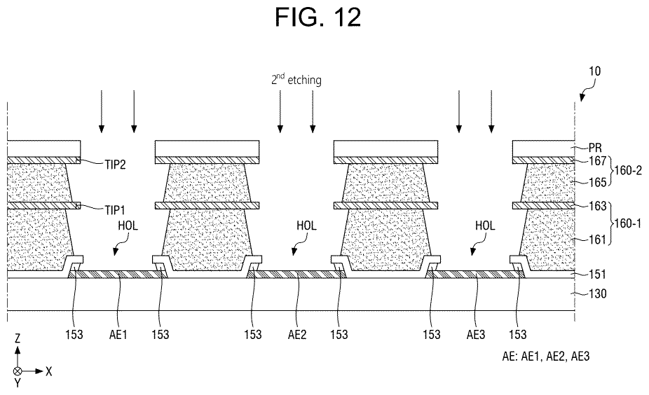

Subsequently, referring to FIGS. 11 and 12, a second etching process of etching the inside of the hole HOL formed to overlap the first to third anode electrodes AE1, AE2 and AE3 is performed. For example, the second etching process may be performed by a wet etching process.

The second bank material layer 163L according to some embodiments may have an etching rate lower than that of the first bank material layer 161L. In other words, the second bank material layer 163L according to some embodiments may have an etching rate lower than that of the first bank material layer 161L. Therefore, in the present process, a side of the second bank material layer 163L may form a first tip TIP1 more protruded toward the hole HOL than a side of the first bank material layer 161L.

In addition, the fourth bank material layer 167L according to some embodiments may have an etching rate lower than that of the third bank material layer 165L. In other words, the fourth bank material layer 167L according to some embodiments may have an etching rate lower than that of the third bank material layer 165L. Therefore, a side of the fourth bank material layer 167L may form a second tip TIP2 more protruded toward the hole HOL than a side of the third bank material layer 165L.

In the present process, the pixel defining material layer 151L may be formed in the form of the pixel defining layer 151 of FIG. 5, and the first to fourth bank material layers 161L, 163L, 165L and 167L may be formed in the form of the first to fourth bank layers 161, 163, 165 and 167. Therefore, the first bank structure 160-1 and the second bank structure 160-2 of FIG. 5 may be formed through the present process.

At the same time, a portion of the sacrificial layer SFL located on the first to third anode electrodes AE1, AE2 and AE3 may be removed in the present process. However, the sacrificial layer SFL may remain a partial residual pattern 153 in a space between the pixel defining material layer 151L and the first to third anode electrodes AE1, AE2 and AE3 without being completely removed. The residual pattern 153 may overlap the first tip TIP1 and the second tip TIP2 in the third direction (Z-axis direction). Other redundant description will be omitted.

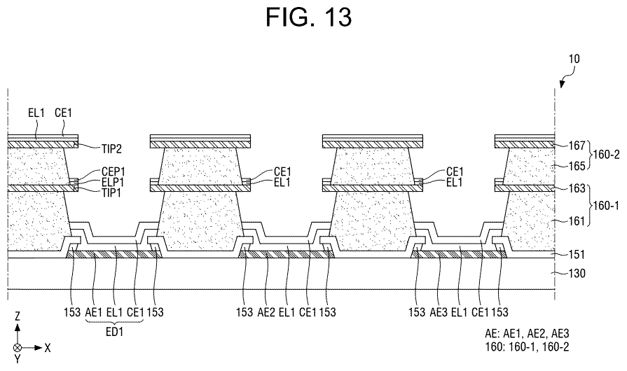

Next, referring to FIG. 13, a first light emitting layer EL1 and a first cathode electrode CE1 are deposited on the first anode electrode AE1, so that a first light emitting element ED1 is formed. The first light emitting layer EL1 and the first cathode electrode CE1 according to some embodiments may be formed through a thermal deposition process. In the display device 10 according to some embodiments, as the second bank layer 163 includes the first tip TIP1, the deposition process of forming the first light emitting layer EL1 and the deposition process of forming the first cathode electrode CE1 may be performed without a separate fine metal mask.

However, the deposition process of forming the first light emitting layer EL1 may be performed by being inclined at an angle of 45° to 50° from the upper surface of the first anode electrode AE1. As a result, the first light emitting layer EL1 may be formed to fill a space where the first anode electrode AE1 and the pixel defining material layer 151L are spaced apart from each other, and may be also formed on a portion of the side of the first bank layer 161 covered by the first tip TIP1.

The deposition process of forming the first cathode electrode CE1 according to some embodiments may be performed by being inclined at an angle of 30° or less from the upper surface of the first anode electrode AE1. In other words, the deposition process of forming the first cathode electrode CE1 may be performed by being inclined to be relatively closer to a horizontal direction than the deposition process of forming the first light emitting layer EL1. As a result, the first cathode electrode CE1 may completely cover the first light emitting layer EL1.

The material of forming the first light emitting layer EL1 and the material of forming the first cathode electrode CE1 according to some embodiments may be formed not only on the first anode electrode AE1 but also on the upper surfaces of the second anode electrode AE2, the third anode electrode AE3, the first tip TIP1 and the fourth bank layer 167. Through the present process, a first organic pattern ELP1 and a first electrode pattern CEP1 may be formed. The first organic pattern ELP1 and the first electrode pattern CEP1 may be formed on the first tip TIP1 of the second bank layer 163 at a portion overlapped with the first anode electrode AE1.

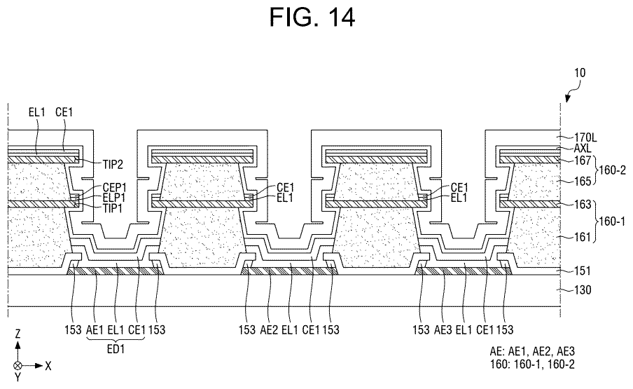

Subsequently, referring to FIG. 14, an auxiliary electrode material layer AXL is entirely formed on the first cathode electrode CE1 and the first electrode pattern CEP1. The auxiliary electrode material layer AXL may completely cover the first cathode electrode CE1, the first bank structure 160-1 and the second bank structure 160-2. The auxiliary electrode material layer AXL may cover the first cathode electrode CE1 and the bank structure 160 at a uniform thickness along a profile formed by the first cathode electrode CE1 and the bank structure 160. The auxiliary electrode material layer AXL arranged in contact with the first cathode electrode CE1 may be integrated with the auxiliary electrode material layer AXL arranged in contact with the bank structure 160.

Subsequently, the thin film encapsulation material layer 170L is entirely formed on the auxiliary electrode material layer AXL. The thin film encapsulation material layer 170L may be performed by a chemical vapor deposition (CVD) process, and may completely cover the auxiliary electrode material layer AXL. The thin film encapsulation material layer 170L may cover the auxiliary electrode material layer AXL at a uniform thickness along a profile formed by the auxiliary electrode material layer AXL.

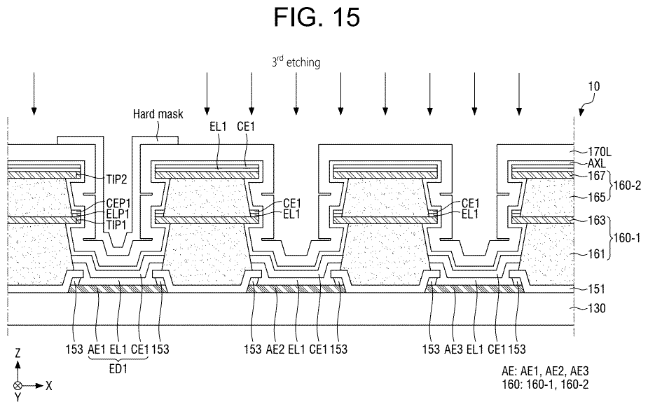

Next, referring to FIG. 15, a hard mask is formed at a portion overlapped with the first light emitting element ED1 and the periphery of the first light emitting element ED1, and a third etching process of etching a portion where the hard mask is not formed is performed. For example, the third etching process may be performed in such a manner that a dry etching process and a wet etching process are alternately performed. In the present process, the first light emitting layer EL1, the first cathode electrode CE1, the auxiliary electrode material layer AXL and the thin film encapsulation material layer 170L, at which the hard mask is not formed, may be all removed. Indium gallium zinc oxide (IGZO) may be used as the hard mask used in the present process.

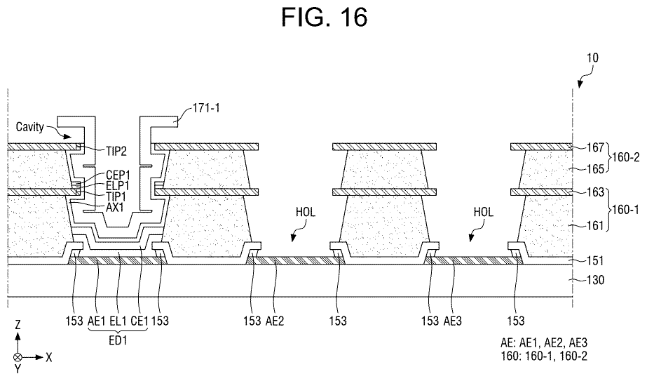

Referring to FIG. 16, through the present process, the auxiliary electrode material layer AXL may be formed in the form of the first auxiliary electrode AX1, and the thin film encapsulation material layer 170L may be formed in the form of the first inorganic layer 171-1. According to the etching process of the present process, a cavity may be formed between the first inorganic layer 171-1 and the fourth bank layer 167 in the third direction (Z-axis direction). That is, the cavity may be formed by etching of the first light emitting layer EL1, the first cathode electrode CE1 and the auxiliary electrode material layer AXL, which are located on the fourth bank layer 167.

In the present process, the second anode electrode AE2 and the third anode electrode AE3 may be exposed again, the residual pattern 153 overlapped with the second anode electrode AE2 and the third anode electrode AE3 may remain, and a hole HOL may be formed in a portion overlapped with the second anode electrode AE2 and the third anode electrode AE3.

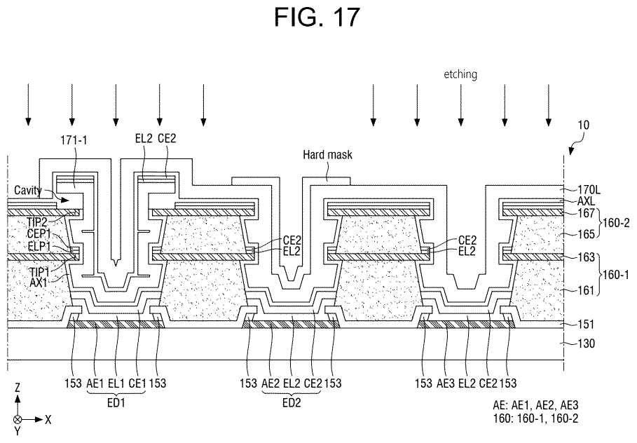

Next, referring to FIG. 17, the above-described processes are repeated so that a second light emitting element ED2 is formed. For example, a second light emitting layer EL2, a second cathode electrode CE2, an auxiliary electrode material layer AXL and a thin film encapsulation material layer 170L are entirely deposited on the second anode electrode AE2. In the present process, the second light emitting layer EL2 and the second cathode electrode CE2 may be formed on the second anode electrode AE2 to form the second light emitting element ED2. In the present process, the second light emitting layer EL2, the second cathode electrode CE2, the auxiliary electrode material layer AXL and the thin film encapsulation material layer 170L may be formed on the first inorganic layer 171-1 and also on the third anode electrode AE3.

Subsequently, a hard mask is formed at a portion overlapped with the second light emitting layer ED2 and the periphery of the second light emitting element ED2, and a portion where the hard mask is not formed is partially etched. The etching process of the present process may be the same as the third etching process.

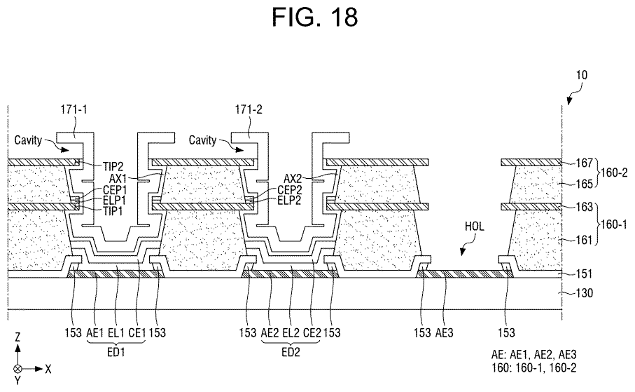

Referring to FIG. 18, a second organic pattern ELP2 and a second electrode pattern CEP2 may be formed through the present process. The second organic pattern ELP2 and the second electrode pattern CEP2 may be formed on the first tip TIP1 of the second bank layer 163 at a portion overlapped with the second anode electrode AE2. Also, the auxiliary electrode material layer AXL may be formed in the form of the second auxiliary electrode AX2, and the thin film encapsulation material layer 170L may be formed in the form of the second inorganic layer 171-2. In the present process, a cavity may be formed between the second inorganic layer 171-2 and the fourth bank layer 167 in the third direction (Z-axis direction). A redundant description will be omitted.

At the same time, the third anode electrode AE3 may be exposed again, the residual pattern 153 overlapped with the third anode electrode AE3 may remain, and a hole HOL may be formed in a portion overlapped with the third anode electrode AE3.

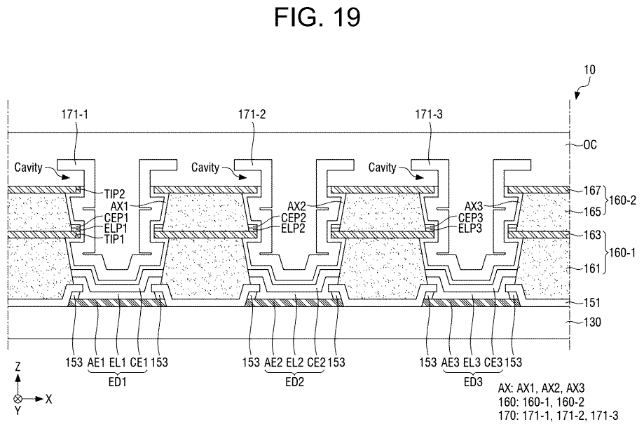

Subsequently, referring to FIG. 19, the above-described processes are repeated so that a third light emitting element ED3 is formed. A redundant description will be omitted.

Through the present process, a third organic pattern ELP3 and a third electrode pattern CEP3 may be formed on the first tip TIP1 of the second bank layer 163 at a portion overlapped with the third anode electrode AE3. In addition, the auxiliary electrode material layer AXL may be formed in the form of the third auxiliary electrode AX3, and the thin film encapsulation material layer 170L may be formed in the form of the third inorganic layer 171-3. In the present process, a cavity may be formed between the third inorganic layer 171-3 and the fourth bank layer 167 in the third direction (Z-axis direction). The third inorganic layer 171-3 according to some embodiments may cover a portion of the fourth bank layer 167, but may not be in contact with the fourth bank layer 167.

Through the present process, the auxiliary electrode AX may have first to third auxiliary electrodes AX1, AX2 and AX3, and the thin film encapsulation layer 170 may have first to third inorganic layers 171-1,171-2 and 171-3.

Subsequently, the overcoat layer OC is entirely formed to planarize a step difference included in the thin film encapsulation layer 170. The overcoat layer OC may be positioned on the thin film encapsulation layer 170 and the fourth bank layer 167, and may fill the inside of the cavity overlapped with the first to third inorganic layers 171-1, 171-2 and 171-3.

As a result, in the display device 10 according to some embodiments, the first and second bank structures 160-1 and 160-2 stacked in the third direction (Z-axis direction) with the first to third light emitting elements ED1, ED2 and ED3 may be formed, and the auxiliary electrode AX and the thin film encapsulation layer 170, which cover the first to third light emitting elements ED1, ED2 and ED3 and the bank structure 160, may be formed. Other redundant description will be omitted.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the principles of the invention. Therefore, the disclosed embodiments of the invention are used in a generic and descriptive sense and not for purposes of limitation.

What is claimed is:

1. A display device comprising:
a substrate including a light emission area and a non-light emission area;
a light emitting layer on the light emission area of the substrate;
a cathode electrode on the light emitting layer;
an auxiliary electrode on the cathode electrode;
a pixel defining layer on the non-light emission area of the substrate, defining a first opening;
a bank structure including a first bank structure on the pixel defining layer and a second bank structure on the first bank structure, defining a second opening;
an organic pattern overlapping the light emission area, on the first bank structure, including a same material as that of the light emitting layer, but spaced apart from the light emitting layer; and
an electrode pattern on the organic pattern, including a same material as that of the cathode electrode but spaced apart from the cathode electrode,
wherein the first bank structure includes a first tip protruded toward the light emission area, and the second bank structure includes a second tip protruded toward the light emission area, and
the organic pattern and the electrode pattern overlap the first tip and the second tip in a direction perpendicular to the substrate.

2. The display device of claim 1, wherein the first bank structure includes a first bank layer; and a second bank layer on the first bank layer, including the first tip, and the second bank structure includes a third bank layer; and a fourth bank layer on the third bank layer, including the second tip.

3. The display device of claim 2, wherein the organic pattern is in contact with the first tip, and
the organic pattern and the electrode pattern are in contact with the third bank layer.

4. The display device of claim 3, wherein the auxiliary electrode is in contact with the first tip and the second tip, and the auxiliary electrode that is in contact with the first tip and the auxiliary electrode that is in contact with the second tip are integrally formed.

5. The display device of claim 4, wherein the first bank layer and the third bank layer have electrical conductivity higher than that of the second bank layer and the fourth bank layer.

6. The display device of claim 2, wherein a side of the first bank layer, which is directed toward the light emission area, includes a first portion with which the light emitting layer is in contact, a second portion with which the cathode electrode is in contact; and a third portion with which the auxiliary electrode is in contact, and
the second portion is between the first portion and the third portion.

7. The display device of claim 6, wherein the side of the first bank layer is completely covered by the light emitting layer, the cathode electrode and the auxiliary electrode.

8. The display device of claim 3, wherein a side of the third bank layer, which is directed toward the light emission area, includes:
a first portion with which the organic pattern is in contact;
a second portion with which the electrode pattern is in contact; and
a third portion with which the auxiliary electrode is in contact, and
the second portion is positioned between the first portion and the third portion.

9. The display device of claim 8, wherein the side of the third bank layer, which is directed toward the light emission area, is completely covered by the organic pattern, the electrode pattern and the auxiliary electrode.

10. The display device of claim 2, wherein the first opening is completely surrounded by the second opening in a plan view, and
the auxiliary electrode is completely surrounded by the fourth bank layer in the plan view.

11. The display device of claim 2, further comprising:
a thin film encapsulation layer positioned on the auxiliary electrode; and
an overcoat layer on the thin film encapsulation layer,
wherein the thin film encapsulation layer and the overcoat layer overlap the first tip and the second tip in a direction perpendicular to the substrate.

12. The display device of claim 11, wherein the thin film encapsulation layer and the overcoat layer overlap the first tip and the second tip in a direction parallel with the substrate.

13. The display device of claim 12, wherein the overcoat layer has a thickness of 8 micrometers (um) or less at a portion that overlaps the non-light emission area and does not overlap the thin film encapsulation layer.

14. A display device comprising:
a substrate including a light emission area and a non-light emission area;
a first light emitting element on the light emission area of the substrate;
a first auxiliary electrode on the first light emitting element;
a pixel defining layer on the non-light emission area of the substrate;
a bank structure on the pixel defining layer, including a first bank layer, a second bank layer, a third bank layer and a fourth bank layer, which are sequentially stacked;
a second light emitting element spaced apart from the first light emitting element with the pixel defining layer interposed therebetween;
a second auxiliary electrode on the second light emitting element;
a thin film encapsulation layer including a first inorganic layer on the first auxiliary electrode and a second inorganic layer on the second auxiliary electrode; and
an overcoat layer on the thin film encapsulation layer,
wherein the fourth bank layer includes a first surface in a direction toward the thin film encapsulation layer,
the first surface is spaced apart from the thin film encapsulation layer in a direction perpendicular to the substrate,
the overcoat layer is positioned between the first surface and the thin film encapsulation layer, and
the first surface is completely covered by the overcoat layer.

15. The display device of claim 14, wherein the second bank layer includes a first tip more protruded to both sides toward the light emission area than both sides of the first bank layer,
the fourth bank layer includes a second tip more protruded to both sides toward the light emission area than both sides of the third bank layer, and
the first auxiliary electrode and the second auxiliary electrode are in contact with the first bank layer, the first tip, the third bank layer and the second tip.

16. The display device of claim 15, wherein the first inorganic layer and the second inorganic layer are spaced apart from each other in a direction parallel with the substrate at a portion overlapped with the non-light emission area.

17. The display device of claim 16, wherein the first auxiliary electrode includes a second surface directed toward the first inorganic layer,
the second auxiliary electrode includes a third surface directed toward the second inorganic layer,
the second surface and the third surface are spaced apart from each other with the first surface interposed therebetween, and
the second surface and the third surface are in contact with the overcoat layer.

18. The display device of claim 15, wherein the first auxiliary electrode and the second auxiliary electrode are in contact with the second tip, but are not in contact with the first surface.

19. The display device of claim 18, wherein the first light emitting element and the second light emitting element are in contact with the first bank layer, and are electrically connected to each other by the first bank layer.

20. A method of fabricating a display device, the method comprising:
forming a substrate including a light emission area and a non-light emission area;
forming an anode electrode on the light emission area;
forming a sacrificial layer on the anode electrode;
forming a pixel defining material layer, a first bank material layer, a second bank material layer, a third bank material layer and a fourth bank material layer, which completely cover the sacrificial layer and the substrate;
forming a photoresist on the fourth bank material layer by exposing a portion overlapped with the anode electrode;
forming a hole exposing the sacrificial layer overlapped with the anode electrode by partially removing the pixel defining material layer, the first bank material layer, the second bank material layer, the third bank material layer and the fourth bank material layer through an etching process, and then removing the sacrificial layer by removing an inner wall of the hole through an etching process and at the same time forming a pixel defining layer, a first bank layer, a second bank layer, a third bank layer and a fourth bank layer by forming a first tip of the second bank material layer, which is more protruded toward the hole than a side of the first bank material layer, and a second tip of the fourth bank material layer, which is more protruded toward the hole than a side of the third bank material layer;
forming a light emitting layer, a cathode electrode, an auxiliary electrode and a thin film encapsulation layer on the anode electrode and the fourth bank layer;
forming a hard mask at a portion overlapped with the light emission area and a periphery of the light emission area;
forming a light emitting element by removing the light emitting layer, the cathode electrode, the auxiliary electrode and the thin film encapsulation layer, which are positioned at portions where the hard mask is not formed, through an etching process, and exposing an upper surface of the fourth bank layer,
wherein the auxiliary electrode is in contact with the first bank layer, the second bank layer, the third bank layer and the fourth bank layer but is not in contact with the upper surface of the fourth bank layer when forming the auxiliary electrode and the thin film encapsulation layer.
